(19) United States
(12) Patent Application Publication
(10) Pub. No.: US 2024/0279542 A1
(43) Pub. Date: Aug. 22, 2024

(54) QUANTUM DOT, OPTICAL MEMBER AND ELECTRONIC APPARATUS INCLUDING THE QUANTUM DOT, AND METHOD OF PREPARING THE QUANTUM DOT

(71) Applicants: Samsung Display Co., Ltd., Yongin-si (KR); Research & Business Foundation SUNGKYUNKWAN UNIVERSITY, Suwon-si (KR)

(72) Inventors: Sunyoung Kwon, Yongin-si (KR); Wanki Bae, Seoul (KR); Kyuri Kim, Suwon-si (KR); Seongbin Im, Suwon-si (KR); Keunchan Oh, Yongin-si (KR); Hyeokjin Lee, Yongin-si (KR)

(73) Assignees: Samsung Display Co., Ltd., Yongin-si (KR); Research & Business Foundation SUNGKYUNKWAN UNIVERSITY, Suwon-si (KR)

(21) Appl. No.: 18/424,088

(22) Filed: Jan. 26, 2024

(30) Foreign Application Priority Data
Feb. 2, 2023 (KR) 10-2023-0014410

(51) Int. Cl. C09K 11/62; B82Y 20/00; B82Y 40/00; H10K 50/115

(52) U.S. Cl. CPC C09K 11/621; H10K 50/115; B82Y 20/00; B82Y 40/00

(57) ABSTRACT

Embodiments provide a quantum dot, an optical member including the quantum dot, an electronic apparatus including the quantum dot, and a method of preparing the quantum dot. The quantum dot includes a core including indium (In) and A¹, and a first shell covering the core, not including In, and including A¹. A¹ is a Group I element, an atomic ratio of A¹ to In in the quantum dot is in a range of about 0.9 to about 2.4, and the quantum dot emits visible light other than blue light.

### CROSS-REFERENCE TO RELATED APPLICATION(S)

This application claims priority to and benefits of Korean Patent Application No. 10-2023-0014410 under 35 U.S.C. § 119, filed on Feb. 2, 2023, in the Korean Intellectual Property Office (KIPO), the entire contents of which are incorporated herein by reference.

### BACKGROUND

### 1. Technical Field

Embodiments relate to a quantum dot, an optical member including the quantum dot, an electronic apparatus including the quantum dot, and a method of preparing the quantum dot.

### 2. Description of the Related Art

Quantum dots can be utilized as materials that perform various optical functions (for example, a light conversion function, a light emission function, and the like) in optical members and various electronic apparatuses. Quantum dots, which are semiconductor nanocrystals with a quantum confinement effect, may have different energy bandgaps by control of the size and composition of the nanocrystals, and thus may emit light of various emission wavelengths.

An optical member including quantum dots may have the form of a thin film, for example, a thin film patterned in each subpixel. Such an optical member may be used as a color conversion member of a device including various light sources.

The quantum dots may be used for a variety of purposes in various electronic apparatuses. For example, the quantum dots may be used as emitters. For example, the quantum dots may be included in an emission layer of a light-emitting device including a pair of electrodes and the emission layer, and may serve as an emitter.

To implement high quality optical members and electronic apparatuses, development of quantum dots having excellent photoluminescence quantum yield (PLQY) without including cadmium, which is a toxic element, is required.

### SUMMARY

Embodiments relate to a novel quantum dot, an optical member including the quantum dot, an electronic apparatus including the quantum dot, and a method of preparing a quantum dot.

Additional aspects will be set forth in part in the description which follows and, in part, will be apparent from the description, or may be learned by practice of the presented embodiments of the disclosure.

According to embodiments, a quantum dot may include
a core including indium (In) and A¹, and
a first shell covering the core, not including In, and including A¹,
wherein A¹ may be a Group I element,
an atomic ratio of A¹ to In in the quantum dot may be in a range of about 0.9 to about 2.4, and
the quantum dot may emit visible light other than blue light.

According to embodiments, the core may further include at least one of A² and B¹, A² may be a Group III element other than In, and B¹ may be a Group VI element.

According to embodiment, the first shell may further include at least one of A³ and B², A³ may be a Group III element other than indium, and B² may be a Group VI element.

According to embodiment, the core and the first shell may each independently include a Group I-III-VI semiconductor compound.

According to embodiment, the core may include a first semiconductor compound represented by Formula 1, which is explained below.

According to embodiment, the first shell may include a second semiconductor compound represented by Formula 2, which is explained below.

According to embodiment, a maximum emission wavelength of the quantum dot may be in a range of about 500 nm to about 650 nm.

According to embodiment, a full width at half maximum (FWHM) of an emission wavelength spectrum of the quantum dot may be in a range of about 30 nm to about 35 nm.

According to embodiment, a photoluminescence quantum yield (PLQY) of the quantum dot may be in a range of about 50% to about 98%.

According to embodiments, an optical member may include the quantum dot.

According to embodiments, an electronic apparatus may include the quantum dot.

According to embodiment, the electronic apparatus may further include a light source, and a color conversion member disposed on a pathway of light emitted from the light source. The color conversion member may include the quantum dot.

According to embodiment, the electronic apparatus may further include a light-emitting device including a first electrode, a second electrode facing the first electrode, and an emission layer between the first electrode and the second electrode. The light-emitting device may include the quantum dot.

According to embodiments, a method of preparing a quantum dot may include manufacturing a core including indium (In) and A¹ by using a first composition including an In-containing precursor and an A¹-containing precursor, and
manufacturing a first shell covering the core and including A¹ by using a second composition including the core and the A¹-containing precursor,
wherein A¹ may be a Group I element.

According to embodiment, an atomic ratio of A¹ to In in the quantum dot may be in a range of about 0.9 to about 2.4, and the quantum dot may emit visible light other than blue light.

According to embodiment, the method may further include manufacturing the A¹-containing precursor in the first composition by using a third composition including an A¹-containing first precursor and a B¹-containing second precursor.

According to embodiment, the A¹-containing precursor in the first composition may be an A¹-B¹-containing precursor which further includes B¹, and B¹ may be a Group VI element.

According to embodiment, the A¹-containing precursor in the first composition may be an A¹-A²-B¹-containing precursor which further includes A² and B¹, A² may be a Group III element other than In, and B¹ may be a Group VI element. The method may further include manufacturing the A¹-A²-B¹-containing precursor by using a fourth composition including an A¹-B¹-containing precursor and an A²-containing precursor, before the manufacturing of the core.

According to embodiment, the first composition may further include an A²-containing precursor, the core may further include A², and A² may be a Group III element other than In.

According to embodiment, the second composition may further include at least one of an A³-containing precursor and a B²-containing precursor, the first shell may further include at least one of A³ and B², A³ may be a Group III element other than indium, and B² may be a Group VI element.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a quantum dot according to an embodiment;

FIG. 2 is a schematic cross-sectional view of a structure of an electronic apparatus according to an embodiment;

FIG. 3 is a schematic cross-sectional view of a structure of a light-emitting device according to an embodiment;

FIG. 4 is a schematic graph showing photoluminescence spectrum of Example 3 and Comparative Examples 1 and 2;

FIG. 5 shows transmission electron microscope (TEM) images of Comparative Example 1 and Examples 1 to 3; and

FIG. 6 shows TEM images of Comparative Examples 1 and 2 and Example 3.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

It will be understood that although the terms “first,” “second,” etc. used herein may be used herein to describe various components, these components should not be limited by these terms. These components are only used to distinguish one component from another. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The term “Group I” as used herein may be a Group IA element or a Group IB element on the IUPAC periodic table, and examples of the Group I element may include silver (Ag), copper (Cu), and the like.

The term “Group II” used herein may be a Group IIA element or a Group IIB element on the IUPAC periodic table, and examples of the Group II element may include magnesium (Mg), calcium (Ca), zinc (Zn), cadmium (Cd), and mercury (Hg).

The term “Group III” used herein may be a Group IIIA element or a Group IIIB element on the IUPAC periodic table, and examples of the Group III element may include aluminum (Al), gallium (Ga), indium (In), and thallium (Tl).

The term “Group IV” used herein may be a Group IVA element or a Group IVB element on the IUPAC periodic table, and examples of the Group IV element may include carbon (C), silicon (Si), germanium (Ge), and tin (Sn).

The term “Group V” used herein may be a Group VA element or a Group VB element on the IUPAC periodic table, and examples of the Group V element may include nitrogen (N) and phosphorous (P).

The term “Group VI” as used herein may be a Group VIA element or a Group VIB element on the IUPAC periodic table, and examples of the Group VI element may include oxygen (O), sulfur (S), selenium (Se), tellurium (Te), and the like.

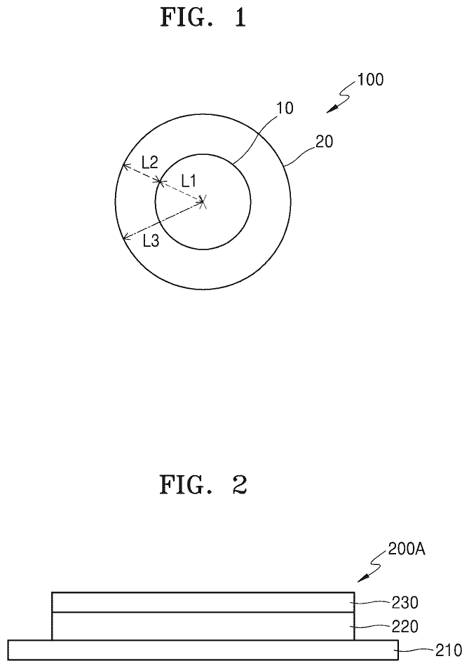

Hereinafter, embodiments of a quantum dot 100 and a method of preparing the same will be described with reference to FIG. 1.

### [Description of FIG. 1]

FIG. 1 is a schematic cross-sectional view of the quantum dot 100 according to an embodiment. The quantum dot 100 may include a core 10 and a first shell 20.

### [Quantum Dot 100]

According to an embodiment, the quantum dot 100 of FIG. 1 may include: the core 10 including In and A¹; and the first shell 20 covering the core 10, not including In, and including A¹,
wherein A¹ may be a Group I element,
an atomic ratio of A¹ to In in the quantum dot 100 may be in a range of about 0.9 to about 2.4, and the quantum dot 100 may emit visible light other than blue light.

In an embodiment, an atomic ratio of A¹ to In in the quantum dot 100 may be in a range of about 0.9 to about 2.4. For example, an atomic ratio of A¹ to In in the quantum dot 100 may be in a range of about 1.0 to about 2.3. For example, the atomic ratio of A¹ to In in the quantum dot 100 may be in a range of about 1.1 to about 2.2. However, the disclosure is not limited thereto.

In the quantum dot 100 of the disclosure, as the core 10 and the first shell 20 each include A¹ to meet a certain atomic ratio, generation of Group I-Group VI or Group III-Group VI byproducts and precipitation of A¹ may be suppressed, which facilitates formation of Group I-Group III-Group VI shell. As the quantum dot 100 has excellent luminescence efficiency and high absorbance while maintaining stability, a high-quality optical member and electronic apparatus may be provided by using the quantum dot 100.

In case that the atomic ratio of A¹ to In in the quantum dot 100 does not satisfy the aforementioned range, for example, the quantum dot 100 including A¹ in an amount exceeding the above range may be difficult to be synthesized because of Group I-Group VI byproducts formed due to an excessive amount of A¹, and the quantum dot 100 including A¹ in an amount that fails to reach the aforementioned range may have an issue of stability and luminescence efficiency may decrease due to insufficient amount of A¹ in the shell.

In an embodiment, the core 10 may further include at least one of A² and B¹,

A² may be a Group III element other than In, and B¹ may be a Group VI element.

In an embodiment, A¹ may be Ag, Cu, or any combination thereof.

In an embodiment, A² may be Al, Ga, Tl, or any combination thereof.

In an embodiment, B¹ may be O, S, Se, Te, or any combination thereof.

In an embodiment, A¹ may be Ag or Cu, A² may be Ga or A¹, and B¹ may be S or Se. For example, A¹ may be Ag, A² may be Ga, and B¹ may be S; however, the disclosure is not limited thereto.

In an embodiment, the core 10 may include a quaternary compound.

The term “quaternary compound” may be a compound including four different elements.

In an embodiment, the core 10 may include a Group I-III-VI semiconductor compound.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and the like; a quaternary compound such as AgInGaS₂, AgInGaSe₂, and the like; or any combination thereof.

In an embodiment, the core 10 may include a first semiconductor compound represented by Formula 1:

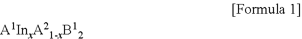

In Formula 1,
A¹ may be a Group I element,
A² may be a Group III element other than In,
B¹ may be a Group VI element, and
x may be in a range of about 0.1 to about 0.6.

In an embodiment, the first shell 20 may further include at least one of A³ and B², A³ may be a Group III element other than indium, and B² may be a Group VI element.

In an embodiment, A³ may be A¹, Ga, Tl, or any combination thereof.

In an embodiment, B² may be O, S, Se, Te, or any combination thereof.

For example, A³ may be Ga, and B² may be S.

In an embodiment, the first shell 20 may include a Group I-III-VI semiconductor compound.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and the like; a quaternary compound such as AgInGaS₂, AgInGaSe₂, and the like; or any combination thereof.

In an embodiment, the first shell 20 may include a second semiconductor compound represented by Formula 2:

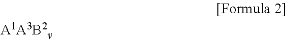

In Formula 2,
A¹ may be a Group I element,
A³ may be a Group III element other than indium,
B² may be a Group VI element, and
y may be a real number in a range of about 0.5 to about 2.

In an embodiment, A¹ included in the core 10 and A¹ included in the first shell 20 may be same.

In an embodiment, A² and A³ may be same.

In an embodiment, B¹ and B² may be same.

In an embodiment, A¹ in the core 10 may be present at a uniform concentration or non-uniform concentration.

In an embodiment, A² in the core 10 may be present at a uniform concentration or non-uniform concentration.

In an embodiment, B¹ in the core 10 may be present at a uniform concentration or non-uniform concentration.

In an embodiment, A¹ in the first shell 20 may be present at a uniform concentration or non-uniform concentration.

In an embodiment, A³ in the first shell 20 may be present at a uniform concentration or non-uniform concentration.

In an embodiment, B² in the first shell 20 may be present at a uniform concentration or non-uniform concentration.

In an embodiment, a radius L1 of the core 10 of the quantum dot 100 may be in a range of about 1 nm to about 10 nm.

In an embodiment, a thickness L2 of the first shell 20 of the quantum dot 100 in a radial direction of the quantum dot 100 may be in a range of about 0.5 nm to about 8 nm.

In an embodiment, a ratio of the thickness L2 of the first shell 20 to the radius L1 of the core 10 may be in a range of about 0.05 to about 8.

For example, the ratio of the thickness L2 of the first shell 20 to the radius L1 of the core 10 may be in a range of about 0.05 to about 8, about 0.05 to about 7.5, about 0.05 to about 7.0, about 0.05 to about 6.5, about 0.05 to about 6.0, about 0.05 to about 5.5, about 0.05 to about 5.0, about 0.05 to about 4.5, about 0.05 to about 4.0, about 0.05 to about 3.5, about 0.05 to about 3.0, about 0.1 to about 7.5, about 0.1 to about 7.0, about 0.1 to about 6.5, about 0.1 to about 6.0, about 0.1 to about 5.5, about 0.1 to about 5.0, about 0.1 to about 4.5, about 0.1 to about 4.0, about 0.1 to about 3.5, about 0.1 to about 3.0, about 0.2 to about 7.0, about 0.2 to about 6.5, about 0.2 to about 6.0, about 0.2 to about 5.5, about 0.2 to about 5.0, about 0.2 to about 4.5, about 0.2 to about 4.0, about 0.2 to about 3.5, about 0.2 to about 3.0, about 0.3 to about 6.5, about 0.4 to about 6.0, about 0.5 to about 5.5, about 0.6 to about 5.0, about 0.7 to about 4.5, about 0.8 to about 4.0, about 0.9 to about 3.5, or about 1.0 to about 3.0; however, the disclosure is not limited thereto.

The term “radius L1 of core” may be a distance from the center of the quantum dot 100 to an interface between the core 10 and the first shell 20.

The term “thickness L2 of first shell” may be a distance from the interface between the core 10 and the first shell 20 to a surface of the first shell 20, i.e., a value obtained by subtracting the radius L1 of the core from a distance L3 from the center of the quantum dot 100 to the surface of the first shell 20.

According to an embodiment, the ratio of the thickness of the first shell 20 to the radius of the core 10 of the quantum dot 100 may be in a range of about 0.05 to about 8, and thus the quantum dot 100 may emit high-color purity green light with excellent luminescence efficiency and stability.

In an embodiment, the quantum dot 100 may further include a second shell (not shown) covering the first shell 20.

In embodiments, the quantum dot 100 may be a spherical, pyramidal, multi-arm, or cubic nanoparticle, nanotube, nanowire, nanofiber, or nanoplate particle.

In an embodiment, the quantum dot 100 may be spherical.

In an embodiment, a maximum emission wavelength the photoluminescence (PL) spectrum of the quantum dot 100 may be in a range of about 500 nm to about 650 nm. For example, a maximum emission wavelength in the PL spectrum of the quantum dot 100 may be in a range of about 505 nm to about 600 nm. For example, a maximum emission wavelength in the PL spectrum of the quantum dot 100 may be in a range of about 510 nm to about 550 nm. For example, a maximum emission wavelength in the PL spectrum of the quantum dot 100 may be in a range of about 510 nm to about 530 nm.

In an embodiment, a photoluminescence efficiency of the quantum dot 100 (or photoluminescence quantum yield (PLQY)) may be in a range of about 50% to about 98%. For example, a photoluminescence efficiency of the quantum dot 100 may be in a range of about 55% to about 97%. For example, a photoluminescence efficiency of the quantum dot 100 may be in a range of about 60% to about 95%.

In an embodiment, the quantum dot 100 may have a full width at half maximum (FWHM) of an emission wavelength spectrum in a range of about 30 nm to about 35 nm. In case that the FWHM of the quantum dot 100 is within this range, color purity or color reproducibility may be improved. Since light emitted through the quantum dot 100 is emitted in all directions, a wide viewing angle may be improved.

In an embodiment, the quantum dot 100 may have a blue light absorbance greater than or equal to about 0.6 (mg/ml). For example, a blue light absorbance of the quantum dot 100 may be greater than or equal to about 0.65 (mg/ml). Accordingly, in case that the quantum dot 100 is applied to a photoconversion layer, as the blue light absorbance is high, photoconversion may be performed with high efficiency, and green color having high color-purity may be implemented.

In an embodiment, the quantum dot 100 may be prepared by a method of preparing a quantum dot described below.

The quantum dot 100 may be synthesized by a wet chemical process, a metal organic chemical vapor deposition process, a molecular beam epitaxy process, or any process similar thereto.

The wet chemical process may be a method including mixing a precursor material with an organic solvent and growing quantum dot particle crystals. During crystal growth, the organic solvent may naturally serve as a dispersant on the surface of the quantum dot crystal and control the growth of the crystal so that the growth of quantum dot particles may be controlled through a process which costs lower, and is more readily performed than vapor deposition methods, such as metal organic chemical vapor deposition (MOCVD) or molecular beam epitaxy (MBE).

The quantum dot 100 may further include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of the Group III-V semiconductor compound may be: a binary compound, such as GaN, GaP, GaAs, GaSb, AlN, AlP, AlAs, AlSb, InN, InP, InAs, InSb, or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or the like; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like; or any combination thereof. In an embodiment, the Group III-V semiconductor compound may further include a Group II element. Examples of the Group III-V semiconductor compound further including the Group II element may include InZnP, InGaZnP, InAlZnP, and the like.

Examples of the Group III-VI semiconductor compound may include: a binary compound, such as GaS, GaSe, GazSes, GaTe, InS, InSe, In₂S₃, In₂Se₃, InTe, and the like; a ternary compound, such as InGaS₃, InGaSes, and the like; or any combination thereof.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and the like; a quaternary compound such as AgInGaS₂, AgInGaSe₂, and the like; or any combination thereof.

Examples of the Group IV-VI semiconductor compound may include: a binary compound, such as SnS, SnSe, SnTe, PbS, PbSe, PbTe, and the like; a ternary compound, such as SnSeS, SnSeTe, SnSTe, PbSeS, PbSeTe, PbSTe, SnPbS, SnPbSe, SnPbTe, and the like; a quaternary compound, such as SnPbSSe, SnPbSeTe, SnPbSTe, and the like; or any combination thereof.

Examples of the Group IV element or compound may include: a single element material, such as Si, Ge, and the like; a binary compound, such as SiC, SiGe, and the like; or any combination thereof.

Each element included in a multi-element compound, such as a binary compound, a ternary compound, and a quaternary compound, may be present at a uniform concentration or at a non-uniform concentration in a particle. For example, the formulae merely show elements included in compounds, and ratios of the elements included in the compounds may vary. For example, AgInxGa₁₋ₓS₂ (x is a real number from 0 to 1) may include AgInGaS₂.

The shell 20 or 30 of the quantum dot 100 may serve as a protective layer which prevents chemical denaturation of the core 10 to maintain semiconductor characteristics, and/or as a charging layer which impart electrophoretic characteristics to the quantum dot. The shell 20 or 30 may be single-layered or multi-layered. The shell 20 may have a concentration gradient in which the concentration of an element decreases toward the core 10.

The shell 20 of the quantum dot 100 may further include a metal oxide, a metalloid oxide, a non-metal oxide, a semiconductor compound, or a combination thereof. Examples of the metal oxide, the metalloid oxide, and the non-metal oxide may include: a binary compound, such as SiO2, Al₂O₃, TiO₂, ZnO, MnO, Mn₂O₃, Mn₃O₄, CuO, FeO, Fe₂O₃, Fe₃O₄, CoO, Co₃O₄, NiO, and the like; a ternary compound, such as MgAl₂O₄, CoFe₂O₄, NiFe₂O₄, CoMn₂O₄, and the like; or any combination thereof. Examples of the semiconductor compound may include as described herein, a Group II-VI semiconductor compound, a Group III-V semiconductor compound, a Group III-VI semiconductor compound, a Group I-III-VI semiconductor compound, a Group IV-VI semiconductor compound, or any combination thereof. Examples of the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Since the energy band gap may be adjusted by controlling the size of the quantum dot 100, light having various wavelength bands may be obtained from the quantum dot emission layer. Accordingly, by using quantum dots 100 of different sizes, a light-emitting device that emits light of various wavelengths may be implemented. In an embodiment, the size of the quantum dots 100 may be selected to emit red light, green light, and/or blue light. The size of the quantum dots 100 may be configured to emit white light by combination of light of various colors.

### [Method of Manufacturing Quantum Dot]

A method of preparing the quantum dot 100 may include: manufacturing a core including In and A¹ by using a first composition including an In-containing precursor and an A¹-containing precursor; and
manufacturing a first shell covering the core and including A¹ by using a second composition including the core and the A¹-containing precursor,
wherein A¹ may be a Group I element.

In an embodiment, an atomic ratio of A¹ to In in the quantum dot 100 may be in a range of about 0.9 to about 2.4, and the quantum dot 100 emit visible light other than blue light.

In an embodiment, the A¹-containing precursor and the In-containing precursor in the first composition may be mixed at a molar ratio in a range of about 0.5 to about 4.5, and the A¹-containing precursor in the second composition and the In-containing precursor in the first composition may be mixed at a molar ratio in a range of about 1 to about 12.

For example, the A¹-containing precursor and the In-containing precursor in the first composition may be mixed at a molar ratio in a range of about 0.5 to about 4.5, about 0.6 to about 4.4, about 0.7 to about 4.3, about 0.8 to about 4.2, about 0.9 to about 4.1, about 1.0 to about 4.0, about 1.1 to about 3.9, about 1.2 to about 3.8, about 1.3 to about 3.7, about 1.4 to about 3.8, about 1.5 to about 3.7, about 1.6 to about 3.6, about 1.7 to about 3.5, about 1.8 to about 3.4, about 1.8 to about 3.3, about 1.9 to about 3.2, or about 2.0 to about 3.1.

For example, the A¹-containing precursor in the second composition and the In-containing precursor of the first composition may be mixed at a molar ratio in a range of about 1 to about 12, about 1 to about 11, about 1 to about 10, about 1 to about 9, about 1 to about 8, about 1 to about 7, about 1 to about 6, about 1 to about 5, about 1 to about 4, about 1 to about 3, about 2 to about 12, about 2 to about 11, about 2 to about 10, about 2 to about 9, about 2 to about 8, about 2 to about 7, about 2 to about 6, about 2 to about 5, about 2 to about 4, about 2 to about 3, about 3 to about 12, about 3 to about 11, about 3 to about 10, about 3 to about 9, about 3 to about 8, about 3 to about 7, about 3 to about 6, about 3 to about 5, about 3 to about 4, about 4 to about 12, about 4 to about 11, about 4 to about 10, about 4 to about 9, about 4 to about 8, about 4 to about 7, about 4 to about 6, about 4 to about 5, about 5 to about 12, about 5 to about 11, about 5 to about 10, about 5 to about 9, about 5 to about 8, about 5 to about 7, about 5 to about 6, about 6 to about 12, about 6 to about 11, about 6 to about 10, about 6 to about 9, about 6 to about 8, about 6 to about 7, about 7 to about 12, about 7 to about 11, about 7 to about 10, about 7 to about 9, about 7 to about 8, about 8 to about 12, about 8 to about 11, about 8 to about 10, about 8 to about 9, about 9 to about 12, about 9 to about 11, about 9 to about 10, about 10 to about 12, about 10 to about 11, or about 11 to about 12.

In the method of preparing the quantum dot 100 according to an embodiment, by using a second composition including the A¹-containing precursor for manufacturing the first shell, the atomic ratio of In to A¹ of the quantum dot prepared according to the method may satisfy the aforementioned range, and generation of Group I-Group VI or Group III-Group IV byproducts and precipitation of A¹ may be suppressed, thereby facilitating shell formation of Group I-Group III-Group VI composition. The quantum dot 100 may have excellent luminescence efficiency and high absorbance while maintaining stability.

In an embodiment, the A¹-containing precursor in the first composition may be an A¹-B¹-containing precursor which further includes B¹, and B¹ may be a Group VI element.

In an embodiment, the A¹-containing precursor in the first composition, for example, the A¹-B¹-containing precursor may include a complex including A¹ and B¹.

In an embodiment, the complex may be a compound obtained by chemically bonding A¹ and B¹. For example, the complex may be a compound represented by A¹_{z}B¹, and z may be integer in a range of 0 to 2. In an embodiment, the complex may be A¹²B¹. For example, the complex may be Ag₂S.

In an embodiment, the A¹-containing precursor in the first composition may be an A¹-A²-B¹-containing precursor which further includes A² and B¹, wherein A² may be a Group III element other than In, and B¹ may be a Group VI element.

In an embodiment, the A¹-A²-B¹-containing precursor in the first composition may include a complex which includes A¹, A², and B¹, for example, AgSGa(OAc)₂.

In an embodiment, the first composition may further include an A²-containing precursor, and the core may further include A², wherein A² may be a Group III element other than In.

For example, the first composition may include an In-containing precursor, an A¹-containing precursor, and an A²-containing precursor.

In an embodiment, the second composition may further include at least one of a A³-containing precursor and a B²-containing precursor, and the first shell may further include at least one of A³ and B², wherein A³ may be a Group III element other than indium, and B² may be a Group VI element.

For example, the second composition may include: the core, the A¹-containing precursor, and the A³-containing precursor; the core, the A¹-containing precursor, and the B²-containing precursor; or the core, the A¹-containing precursor, the A³-containing precursor, and the B²-containing precursor.

In an embodiment, the method of preparing the quantum dot 100 may further include manufacturing the A¹-containing precursor in the first composition by using a third composition including an A¹-containing first precursor and a B¹-containing second precursor.

For example, after forming the A¹-containing precursor by using the third composition including the A¹-containing first precursor and the B¹-containing second precursor, the manufacturing of the core and the manufacturing of the first shell may be performed. For example, due to B¹ that is provided in the B¹-containing second precursor, the A¹-containing precursor may include B¹.

In an embodiment, the A¹-containing precursor formed by using the third composition including the A¹-containing first precursor and the B¹-containing second precursor may be an A¹-B¹-containing precursor.

In an embodiment, the method of preparing the quantum dot 100 may further include manufacturing an A¹-B¹-containing precursor in a fourth composition by using the third composition including the A¹-containing first precursor and the B¹-containing second precursor.

In an embodiment, the method of preparing the quantum dot 100 may further include manufacturing an A¹-A²-B¹-containing precursor by using the fourth composition including the A¹-B¹-containing precursor and an A²-containing precursor.

In an embodiment, the method of preparing the quantum dot 100 may further include manufacturing an A¹-A²-B¹-containing precursor by using the fourth composition including the A¹-B¹-containing precursor and an A²-containing precursor, before the manufacturing of the core including In and A¹.

In an embodiment, the method may further include manufacturing an A¹-A²-B¹-containing precursor by using the fourth composition including the A¹-B¹-containing precursor formed by using the third composition and an A²-containing precursor, after the manufacturing of the A¹-B¹-containing precursor by using the third composition including the A¹-containing first precursor and the B¹-containing second precursor. For example, the method may further include manufacturing an A¹-B¹-containing precursor and manufacturing an A¹-A²-B¹-containing precursor, before the manufacturing of the core including In and A¹.

In an embodiment, the fourth composition may include an A¹-B¹-containing precursor and an A²-containing precursor, and may further include an A³-containing precursor. In an embodiment, A² and A³ may be same. For example, the fourth composition may include an A¹-B¹-containing precursor and an A²-containing precursor. For example, the fourth composition may include an A¹-B¹-containing precursor, an A²-containing precursor, and an A³-containing precursor.

In an embodiment, the A¹-A²-B¹-containing precursor may include A¹, A², and B¹, and may further include A³. In an embodiment, A² and A³ may be same. For example, the A¹-A²-B¹-containing precursor may include A¹, A², and B¹. For example, the A¹-A²-B¹-containing precursor may include A¹, A², A³, and B¹.

A¹, A², A³, B¹, and B² may be understood by referring to the descriptions above.

Throughout the specification, the terms “X-containing precursor,” “X-containing first precursor,” and “X-containing second precursor” may be, for example, X, X-containing halide, X-containing carbonate, X-containing nitrate, X-containing nitride, X-containing oxide, X-containing sulfide, X-containing organic compound, or any combination thereof.

For example, the term “indium-containing precursor” may be, for example, indium, indium-containing halide (e.g., InBr₃, InI₃, and the like), indium-containing carbonate (e.g., In₂(CO₃)₃, and the like), indium-containing nitrate (e.g., In(NO₃)₃, and the like), indium-containing nitride, indium-containing oxide (e.g., In₂O₃, and the like), indium-containing sulfide (e.g., In₂Ss, and the like), indium-containing organic compound (e.g., In(C₂H₃O₂)₃, In(OAc)₃, and the like), or any combination thereof.

For example, “silver (Ag)-containing precursor” as an embodiment of “A¹-containing precursor”, may be, for example, silver, silver-containing halide (e.g., AgBr, AgI, and the like), silver-containing carbonate (e.g., Ag₂CO₃, and the like), silver-containing nitrate (e.g., AgNO₃, and the like), silver-containing nitride, silver-containing oxide (e.g., Ag₂O, and the like), silver-containing sulfide (e.g., Ag₂S, and the like), silver-containing organic compound (e.g., Ag(C₂H₃O₂), and the like), or any combination thereof.

For example, “sulfur (S)-containing precursor” as an embodiment of “B¹-containing precursor” may be, for example, sulfur, sulfur-containing organic acid salt, sulfur-containing halide, sulfur-containing carbonate, sulfur-containing nitrate, sulfur-containing nitride, sulfur-containing oxide, sulfur-containing sulfide, sulfur-containing acetate, sulfur-containing organic compound (e.g., S-(oleylamine), S-(1-dodecanethiol), TBP-S, TOP-S, S-(oleic acid), S-(1-octadecene), and the like), or any combination thereof.

In an embodiment, “A²-containing precursor”, “A³-containing precursor”, “B²-containing precursor”, “A¹-containing first precursor”, and “B²-containing second precursor” may be understood by the descriptions provided above.

With respect to the “X-containing precursor”, “X-containing first precursor”, and/or “X-containing second precursor” in the specification, the method of preparing the quantum dot 100 according to an embodiment may further include manufacturing “X-containing precursor”, “X-containing first precursor”, and/or “X-containing second precursor”.

In an embodiment, the manufacturing of the core may include preparing a first composition including an In-containing precursor and an A¹-containing precursor, and after the preparing of the first composition, the manufacturing of the core may further include heating the first composition, wherein the heating is performed in a range of about 150° C. to about 250° C.

For example, the heating may be performed in a range of about 150° C. to about 250° C. For example, the heating may be performed in a range of about 160° C. to about 240° C. For example, the heating may be performed in a range of about 170° C. to about 230° C. For example, the heating may be performed in a range of about 180° C. to about 220° C. For example, the heating may be performed in a range of about 185° C. to about 215° C.

In an embodiment, the method may further include cleaning the core after the manufacturing of the core, and may further include manufacturing the first shell after the cleaning of the core.

In an embodiment, the manufacturing of the first shell may include preparing a second composition including the core and an A¹-containing precursor, and may further include heating the second composition, wherein the heating may be performed in a range of about 180° ° C. to about 300° C.

For example, the heating may be performed in a range of about 180° C. to about 300° C. For example, the heating may be performed in a range of about 190° C. to about 290° ° C. For example, the heating may be performed in a range of about 200° C. to about 280° C. For example, the heating may be performed in a range of about 210° C. to about 270° C. For example, the heating may be performed in a range of about 220° C. to about 260° C. For example, the heating may be performed in a range of about 230° C. to about 255° C.

In an embodiment, the manufacturing of the A¹-B¹-containing precursor may include preparing a third composition including an A¹-containing first precursor and a B¹-containing second precursor, and may further include after the manufacturing of the third composition, heating the third composition, wherein the heating may be performed in a range of about 30° C. to about 80° C.

For example, the heating may be performed in a range of about 30° C. to about 80° C. For example, the heating may be performed in a range of about 35° C. to about 75° ° C. For example, the heating may be performed in a range of about 40° C. to about 70° C. For example, the heating may be performed in a range of about 45° C. to about 65° C. For example, the heating may be performed in a range of about 45° C. to about 60° C.

In an embodiment, the manufacturing of the A¹-A²-B¹-containing precursor may include preparing a fourth composition including an A¹-B¹-containing precursor and an A²-containing second precursor, and may further include after the manufacturing of the fourth composition, heating the fourth composition, wherein the heating may be performed in a range of about 130° C. to about 250° C.

For example, the heating may be performed in a range of about 130° C. to about 250° C. For example, the heating may be performed in a range of about 130° C. to about 240° C. For example, the heating may be performed in a range of about 130° C. to about 230° C. For example, the heating may be performed in a range of about 130° C. to about 220° C. For example, the heating may be performed in a range of about 130° C. to about 210° C. For example, the heating may be performed in a range of about 130° C. to about 200° C. For example, the heating may be performed in a range of about 130° C. to about 190° C. For example, the heating may be performed in a range of about 130° C. to about 180° C. For example, the heating may be performed in a range of about 130° C. to about 170° C.

### First Embodiment

In an embodiment, the method of preparing the quantum dot 100 may include manufacturing an A¹-containing precursor in the first composition by using a third composition including an A¹-containing first precursor and a B¹-containing second precursor.

The method of preparing the quantum dot 100 may include: manufacturing a core including In and A¹ by using a first composition including an In-containing precursor and an A¹-containing precursor; and

manufacturing a first shell covering the core and including A¹ by using a second composition including the core and the A¹-containing precursor.

The A¹-containing precursor in the first composition may be an A¹-B¹-containing precursor which further includes B¹, and B¹ may be a Group VI element.

However, the first embodiment is not limited to the foregoing, and all descriptions about preparation of the quantum dots may be applied to the first embodiment as well.

### Second Embodiment

In an embodiment, the method of preparing the quantum dot 100 may include manufacturing the A¹-B¹-containing precursor in the fourth composition by using the third composition including the A¹-containing first precursor and the B¹-containing second precursor.

In an embodiment, the method of preparing the quantum dot 100 may further include manufacturing an A¹-A²-B¹-containing precursor by using the fourth composition including the A¹-B¹-containing precursor and the A²-containing precursor.

The method of preparing the quantum dot 100 may include: manufacturing a core including In and A¹ by using a first composition including an In-containing precursor and an A¹-containing precursor; and
manufacturing a first shell covering the core and including A¹ by using a second composition including the core and the A¹-containing precursor.

In an embodiment, the A¹-containing precursor in the first composition may be an A¹-A²-B¹-containing precursor which further includes A² and B¹, wherein A² may be a Group III element other than In, and B¹ may be a Group VI element.

However, the second embodiment is not limited to the foregoing, and all descriptions about preparation of the quantum dots may be applied to the first embodiment as well.

### [Optical Member]

The quantum dot may be used in various optical members. According to an embodiment, an optical member may include the quantum dot 100.

In embodiments, the optical member may be a light control member.

In embodiments, the optical member may be a color filter, a color conversion member, a capping layer, a light-extraction efficiency enhancement layer, a selective light-absorption layer, or a polarizing layer.

### [Apparatus]

The quantum dot may be used in various electronic apparatuses. According to an embodiment, an electronic apparatus may include the quantum dot 100.

According to an embodiment, an electronic apparatus may include a light source, and a color conversion member located on a pathway of light emitted from the light source, wherein the color conversion member may include the quantum dot.

FIG. 2 is a schematic side view illustrating a structure of an electronic apparatus 200A according to an embodiment. The electronic apparatus 200A of FIG. 2 may include a substrate 210, a light source 220 arranged on the substrate 210, and a color conversion member 230 arranged on the light source 220.

For example, the light source 220 may be a light-emitting device used in liquid crystal displays (LCD), a fluorescent lamp, a light-emitting device, an organic light-emitting device, a quantum-dot light-emitting device (QLED), or any combination thereof. The color conversion member 230 may be arranged on a path of light emitted from the light source 220.

At least a portion of the color conversion member 230 in the electronic apparatus 200A may include the quantum dot, and the portion may absorb light emitted from the light source and emit green light having a maximum emission wavelength in a range of about 500 nm to about 650 nm.

Although the color conversion member 230 is arranged on a path of the light emitted from the light source 220, such an arrangement may not exclude other elements from being further included between the color conversion member 230 and the light source 220.

In an embodiment, between the light source 220 and the color conversion member 230, a polarizing plate, a liquid crystal layer, a light guide plate, a diffusion plate, a prism sheet, a microlens sheet, a luminance enhancing sheet, a reflective film, a color filter, or any combination thereof may be additionally arranged.

In another embodiment, a polarizing plate, a liquid crystal layer, a light guide plate, a diffusion plate, a prism sheet, a microlens sheet, a luminance enhancing sheet, a reflective film, a color filter, or any combination thereof may be additionally arranged on the color conversion member 230.

The electronic apparatus 200A illustrated in FIG. 2 according to an embodiment according to the disclosure may have various shapes, and accordingly, may include various structures.

In embodiments, the electronic apparatus 200A may include a structure including a light source, a light guide plate, a color conversion member, a first polarizing plate, a liquid crystal layer, a color filter, and a second polarizing plate that are sequentially arranged.

In embodiments, the electronic apparatus 200A may include a structure including a light source, a light guide plate, a first polarizing plate, a liquid crystal layer, a second polarizing plate, and a color conversion member that are sequentially arranged.

In the embodiments described above, the color filter may include a pigment or a dye. In the embodiments described above, one of the first polarizing plate and the second polarizing plate may be a vertical polarizing plate, and another one of the first polarizing plate and the second polarizing plate may be a horizontal polarizing plate.

According to an embodiment, the quantum dot as described in the specification may be used as an emitter. According to another embodiment, the electronic apparatus 200A including a light-emitting device may include a first electrode, a second electrode facing the first electrode, and an emission layer arranged between the first electrode and the second electrode, wherein the light-emitting device (for example, the emission layer of the light-emitting device) may include a quantum dot. The light-emitting device may further include a hole transport region between the first electrode and the emission layer, an electron transport region between the emission layer and the second electrode, or a combination thereof.

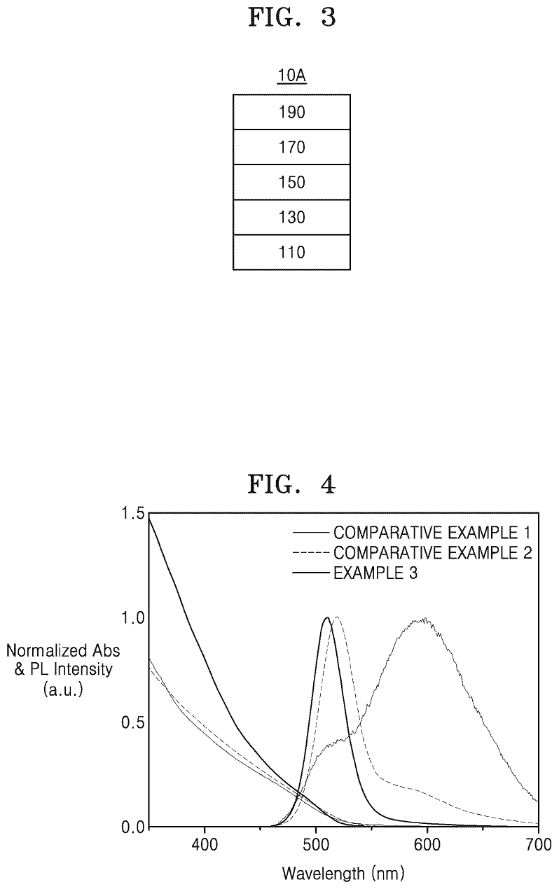

FIG. 3 is a schematic cross-sectional view illustrating a structure of a light-emitting device 10A according to an embodiment.

The light-emitting device 10A may include a first electrode 110, a second electrode 190 facing the first electrode 110, an emission layer 150 disposed between the first electrode 110 and the second electrode 190 and including a quantum dot, a hole transport region 130 disposed between the first electrode 110 and the emission layer 150, and an electron transport region 170 disposed between the emission layer 150 and the second electrode 190. Hereinafter, the layers of the light-emitting device 10A will be described.

### [First Electrode 110]

A substrate may be disposed under the first electrode 110 or above the second electrode 190. The substrate may be a glass substrate or a plastic substrate, having excellent mechanical strength, thermal stability, transparency, surface smoothness, ease of handling, and water resistance.

For example, in case that the light-emitting device 10A is a top-emission type in which light is emitted in a direction opposite to the substrate, the substrate may not be necessarily transparent, and may be opaque or semi-transparent. The substrate may be formed of a metal. In case that the substrate is formed of a metal, the substrate may include carbon, iron, chromium, manganese, nickel, titanium, molybdenum, stainless steel, an Invar alloy, an Inconel alloy, a Kovar alloy, or any combination thereof.

Although not illustrated in FIG. 3, a buffer layer, a thin-film transistor, an organic insulating layer, or the like may be further included between the substrate and the first electrode 110.

The first electrode 110 may be formed by, for example, depositing or sputtering a material for forming the first electrode 110 on the substrate. The first electrode 110 may be a reflective electrode, a semi-transmissive electrode, or a transmissive electrode. To form the first electrode 110 which is a transmission-type electrode, the material for the first electrode may include indium tin oxide (ITO), indium zinc oxide (IZO), tin oxide (SnO₂), zinc oxide (ZnO), gallium zinc oxide (GZO), aluminum zinc oxide (AZO), InZnSnOₓ (IZSO), ZnSnOₓ (ZSO), graphene, PEDOT:PSS, carbon nanotubes, silver (Ag) nanowire, gold (Au) nanowire, metal mesh, or any combination thereof. In embodiments, in case that the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combinations thereof.

The first electrode 110 may have a single-layered structure or a multi-layered structure including two or more layers. For example, the first electrode 110 may have a three-layer structure of ITO/Ag/ITO.

### [Hole Transport Region 130]

The hole transport region 130 may have a structure consisting of a layer including a single material, a structure consisting of a layer including different materials, or a structure including multiple layers including different materials.

The hole transport region 130 may include a hole injection layer, a hole transport layer, an emission auxiliary layer, an electron blocking layer, or any combination thereof.

For example, the hole transport region 130 may have a single-layered structure including a single layer including multiple different materials, or a multi-layered structure of a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, in which the layers of each structure may be stacked from the first electrode 110 in its respective stated order, but the structure of the hole transport region 130 is not limited thereto.

The hole transport region 130 may include an amorphous inorganic material or organic material. The amorphous inorganic material may include NiO, MoO₃, Cr₂O₃, or Bi₂O₃. The amorphous inorganic material may include: a p-type inorganic semiconductor, for example, a p-type inorganic semiconductor in which an iodide, bromide, or chloride of Cu, Ag or Au is doped with a non-metal such as O, S, Se or Te; a p-type inorganic semiconductor in which a Zn-containing compound is doped with a metal, such as Cu, Ag or Au, and a non-metal, such as N, P, As, Sb or Bi; or a spontaneous p-type inorganic semiconductor such as ZnTe.

The organic material may include m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl) triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate (PANI/PSS), polyvinylcarbazole (PVK), a compound represented by Formula 201, a compound represented by Formula 202, or any combination thereof:

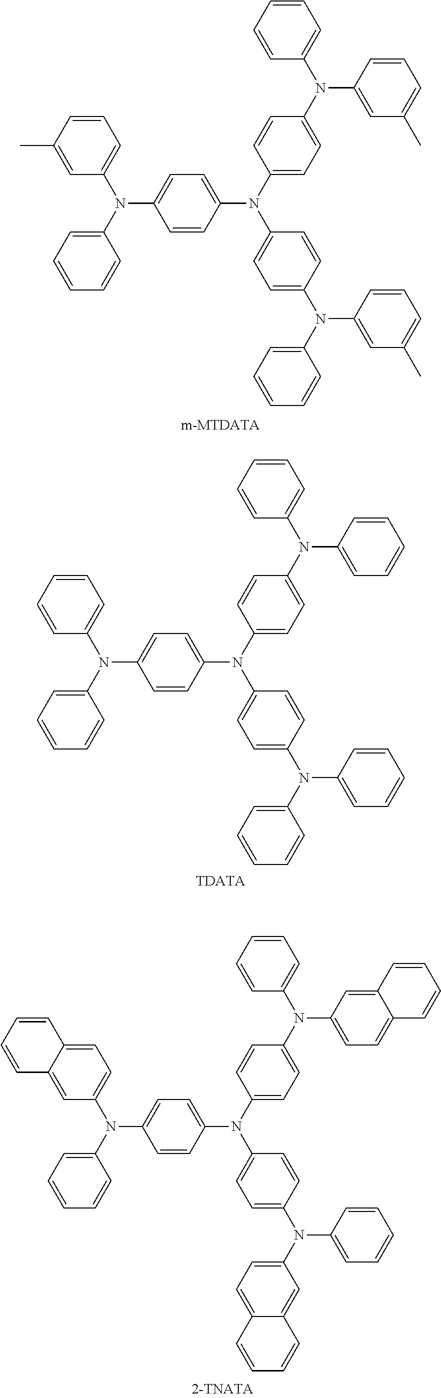

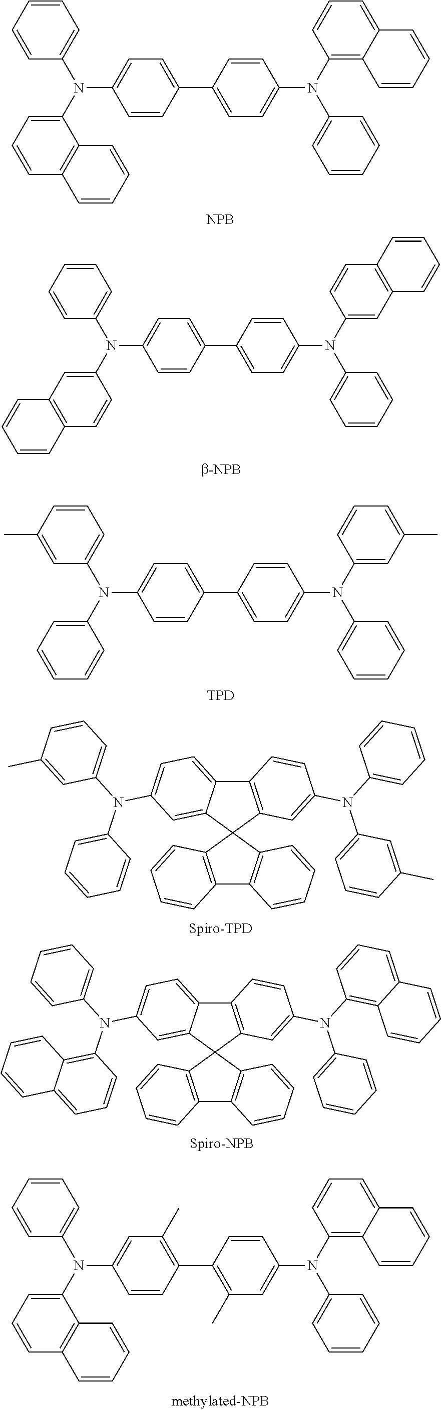

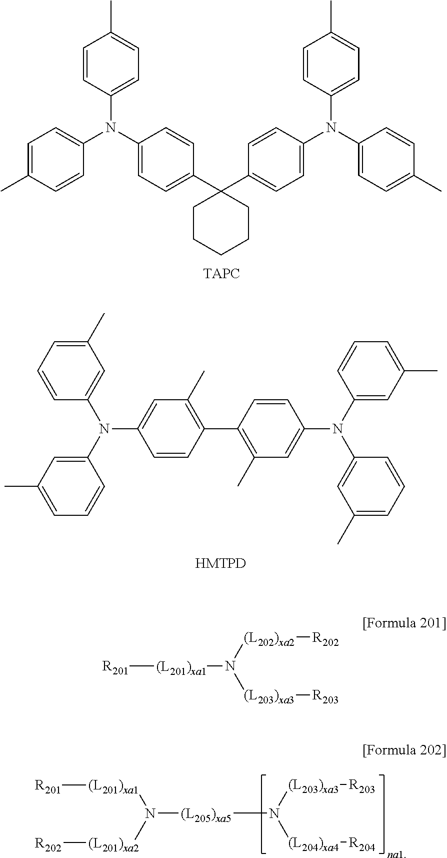

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—**, *—S—**, *—N(Q₂₀₁)-**, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ (for example, a carbazole group),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

The hole transport region 130 may have a thickness in a range of about 50 Å to about 10,000 Å. For example, the thickness of the hole transport region 130 may be in a range of about 100 Å to about 4,000 Å. In case that the hole transport region 130 includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å, and the thickness of the hole transport layer may be in a range of about 100 Å to about 1,500 Å. In case that the thicknesses of the hole transport region 130, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to a wavelength of light emitted by the emission layer, and the electron blocking layer may block the leakage of electrons from the emission layer to the hole transport region 130. Materials that may be included in the hole transport region 130 may be included in the emission auxiliary layer and the electron blocking layer.

[p-Dopant]

The hole transport region 130 may further include, in addition to the materials as described above, a charge-generation material for the improvement of conductive characteristics. The charge-generation material may be uniformly or non-uniformly dispersed in the hole transport region 130 (for example, in the form of a single layer consisting of a charge generation material).

The charge-generation material may be, for example, a p-dopant.

For example, the p-dopant may have a lowest unoccupied molecular orbital (LUMO) energy level of less than or equal to about −3.5 eV.

In an embodiment, the p-dopant may include a quinone derivative, a cyano group-containing compound, a compound including element EL1 and element EL2, or any combination thereof.

Examples of the quinone derivative may include TCNQ, F4-TCNQ, and the like.

Examples of the cyano group-containing compound may include HAT-CN, a compound represented by Formula 221, and the like:

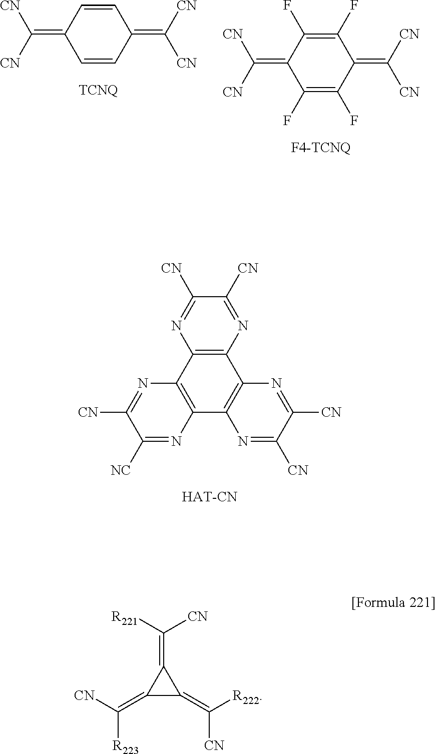

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal may include an alkali metal (for example, lithium (Li), sodium (Na), potassium (K), rubidium (Rb), cesium (Cs), and the like); an alkaline earth metal (for example, beryllium (Be), magnesium (Mg), calcium (Ca), strontium (Sr), barium (Ba), and the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and the like); a post-transition metal (for example, zinc (Zn), indium (In), tin (Sn), and the like); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and the like).

Examples of the metalloid may include silicon (Si), antimony (Sb), tellurium (Te), and the like.

Examples of the non-metal may include oxygen (O), halogen (for example, F, Cl, Br, I, and the like), and the like.

Examples of the compound including element EL1 and element EL2 may include a metal oxide, a metal halide (for example, a metal fluoride, a metal chloride, a metal bromide, a metal iodide, and the like), a metalloid halide (for example, a metalloid fluoride, a metalloid chloride, a metalloid bromide, a metalloid iodide, and the like), a metal telluride, or any combination thereof.

Examples of the metal oxide may include tungsten oxide (for example, WO, W₂O₃, WO₂, WO₃, W₂O₅, and the like), vanadium oxide (for example, VO, V₂O₃, VO₂, V₂O₅, and the like), molybdenum oxide (MoO, Mo₂O₃, MoO₂, MoO₃, Mo₂O₅, and the like), rhenium oxide (for example, ReOs, and the like), and the like.

Examples of the metal halide may include an alkali metal halide, an alkaline earth metal halide, a transition metal halide, a post-transition metal halide, a lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, Rbl, CsI, and the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide may include a titanium halide (for example, TiF₄, TiCl₄, TiBr₄, TiI₄, and the like), a zirconium halide (for example, ZrF₄, ZrCl₄, ZrBr₄, ZrI₄, and the like), a hafnium halide (for example, HfF₄, HfCl₄, HfBr₄, HfI₄, and the like), a vanadium halide (for example, VF₃, VCl₃, VBr₃, VI₃, and the like), a niobium halide (for example, NbF₃, NbCl₃, NbBr₃, NbI₃, and the like), a tantalum halide (for example, TaF₃, TaCl₃, TaBr₃, TaI₃, and the like), a chromium halide (for example, CrF₃, CrCl₃, CrBr₃, CrI₃, and the like), a molybdenum halide (for example, MoF₃, MoCl₃, MoBr₃, MoI₃, and the like), a tungsten halide (for example, WF₃, WCl₃, WBr₃, WI₃, and the like), a manganese halide (for example, MnF₂, MnCl₂, MnBr₂, MnI₂, and the like), a technetium halide (for example, TcF₂, TcCl₂, TcBr₂, TcI₂, and the like), a rhenium halide (for example, ReF₂, ReCl₂, ReBr₂, ReI₂, and the like), an iron halide (for example, FeF₂, FeCl₂, FeBr₂, FeI₂, and the like), a ruthenium halide (for example, RuF₂, RuCl₂, RuBr₂, RuI₂, and the like), an osmium halide (for example, OsF₂, OsCl₂, OsBr₂, OsI₂, and the like), a cobalt halide (for example, CoF₂, CoCl₂, CoBr₂, CoI₂, and the like), a rhodium halide (for example, RhF₂, RhCl₂, RhBr₂, RhI₂, and the like), a iridium halide (for example, IrF₂, IrCl₂, IrBr₂, IrI₂, and the like), a nickel halide (for example, NiF₂, NiCl₂, NiBr₂, NiI₂, and the like), a palladium halide (for example, PdF₂, PdCl₂, PdBr₂, PdI₂, and the like), a platinum halide (for example, PtF₂, PtCl₂, PtBr₂, PtI₂, and the like), a copper halide (for example, CuF, CuCl, CuBr, CuI, and the like), a silver halide (for example, AgF, AgCl, AgBr, AgI, and the like), a gold halide (for example, AuF, AuCl, AuBr, Aul, and the like), and the like.

Examples of the post-transition metal halide may include a zinc halide (for example, ZnF₂, ZnCl₂, ZnBr₂, ZnI₂, and the like), an indium halide (for example, InI₃, and the like), a tin halide (for example, SnI₂, and the like), and the like.

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, and SmI₃.

Examples of the metalloid halide may include an antimony halide (for example, SbCl₅, and the like) and the like.

Examples of the metal telluride may include an alkali metal telluride (for example, Li₂Te, Na₂Te, K₂Te, Rb₂Te, Cs₂Te, and the like), an alkaline earth metal telluride (for example, BeTe, MgTe, CaTe, SrTe, BaTe, and the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and the like), a post-transition metal telluride (for example, ZnTe, and the like), a lanthanide metal telluride (for example, LaTe, CeTe, PrTe, NdTe, PmTe, EuTe, GdTe, TbTe, DyTe, HoTe, ErTe, TmTe, YbTe, LuTe, and the like), and the like.

### [Emission Layer 150]

The emission layer 150 may be a quantum-dot single layer or a structure in which two or more quantum-dot layers are stacked each other. For example, the emission layer 150 may be a quantum-dot single layer or a structure in which 2 to 100 quantum-dot layers are stacked each other.

The emission layer 150 may include the quantum dot as described in the specification.

The emission layer 150 may further include, in addition to the quantum dot as described in the specification, a dispersion medium in which the quantum dots are dispersed in a naturally coordinated form. The dispersion medium may include an organic solvent, a polymer resin, or any combination thereof. The dispersion medium may be a transparent medium that does not affect the optical performance of the quantum dot, is not deteriorated by light, does not reflect light, or does not absorb light. For example, the solvent may include toluene, chloroform, ethanol, octane, or any combination thereof, and the polymer resin may include an epoxy resin, a silicone resin, a polystyrene resin, an acrylate resin, or any combination thereof.

The emission layer 150 may be formed by coating, on the hole transport region 130, a quantum dot-containing composition for forming the emission layer, and volatilizing a portion or more of the solvent from the composition for forming the emission layer.

For example, as the solvent, water, hexane, chloroform, toluene, octane, or the like may be used.

The coating of the composition for forming the emission layer may be performed using a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, or the like.

In case that the light-emitting device 10A is a full-color light-emitting device, the emission layer 150 may include emission layers that emit light of different colors according to individual subpixels.

For example, the emission layer 150 may be patterned into a first-color emission layer, a second-color emission layer, and a third-color emission layer according to individual subpixels. Here, at least one emission layer of the emission layers described above may essentially include the quantum dot. For example, the first-color emission layer may be a quantum-dot emission layer including the quantum dot, and the second-color emission layer and the third-color emission layer may be organic emission layers including organic compounds, respectively. The first color through the third color may be different colors, and for example, the first color through the third color may have different maximum emission wavelengths. The first color through the third color may be white when combined with each other.

In embodiments, the emission layer 150 may further include a fourth-color emission layer, and at least one emission layer of the first-color to third-color emission layers may be a quantum-dot emission layer including the quantum dot, and the remaining emission layers may be organic emission layers including organic compounds, respectively. Other various modifications may be possible. The first color through the fourth color may be different colors, and for example, the first color through the fourth color may have different maximum emission wavelengths. The first color through the fourth color may be white when combined with each other.

In an embodiment, the light-emitting device 10A may have a stacked structure in which two or more emission layers that emit light of identical or different colors contacting each other or separated from each other. At least one of the at least two emission layers may be a quantum dot emission layer including the quantum dots, and another one of the at least two emission layers may be an organic emission layer including organic compounds. For example, the light-emitting device 10A may include a first-color emission layer and a second-color emission layer, and the first color and the second color may be the same color or different colors. In an embodiment, both the first color and the second color may be green or blue.

The emission layer 150 may further include, in addition to the quantum dot, at least one of an organic compound and a semiconductor compound.

In an embodiment, the organic compound may include a host and a dopant. The host and the dopant may include a host and a dopant that are commonly used in organic light-emitting devices.

In an embodiment, the semiconductor compound may be an organic and/or inorganic perovskite.

### [Electron Transport Region 170]

The electron transport region may have a structure consisting of a layer consisting of a single material, a structure consisting of a layer including different materials, or) a structure including multiple layers including different materials.

The electron transport region 170 may include at least one of a buffer layer, a hole blocking layer, an electron control layer, an electron transport layer, and an electron injection layer. However, the disclosure is not limited thereto.

For example, the electron transport region 170 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure. The layers of each structure may be stacked from the emission layer in its respective stated order. However, the disclosure is not limited thereto.

The electron transport region 170 may include a conductive metal oxide. Examples of the conductive metal oxide may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, A¹-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiOs, Al-doped SrTiOs, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

The organic material may include a compound of the related art having an electron transport capability, such as 2,9-dimethyl-4,7-diphenyl-1,10-phenanthroline (BCP), 4,7-diphenyl-1,10-phenanthroline (Bphen), Alq3, BAlq, 3-(biphenyl-4-yl)-5-(4-tert-butylphenyl)-4-phenyl-4H-1,2,4-triazole (TAZ), NTAZ, or the like:

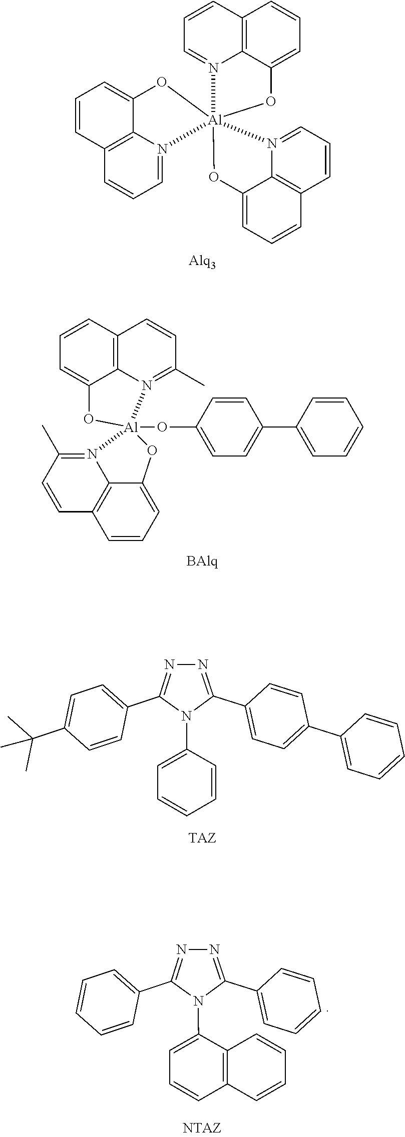

The organic material may be a metal-free compound including at least one TT electron-deficient nitrogen-containing C₁-C₆₀ cyclic group.

For example, the electron transport region 170 may include a compound represented by Formula 601:

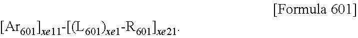

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a IT electron-deficient nitrogen-containing C₁-C₆₀ cyclic group unsubstituted or substituted with at least one R₁₀ₐ.

The electron transport region 170 may have a thickness in a range of about 160 Å to about 5,000 Å. For example, the thickness of the electron transport region 170 may be in a range of about 100 Å to about 4,000 Å. In case that the electron transport region 170 includes a buffer layer, a hole-blocking layer, an electron control layer, an electron transport layer, or any combination thereof, a thickness of the buffer layer, the hole-blocking layer, and the electron control layer may each independently be in a range of about 20 Å to about 1,000 Å, and a thickness of the electron transport layer may be in a range of about 100 Å to about 1,000 Å. For example, the thickness of each of the buffer layer, the hole-blocking layer, and the electron control layer may be in a range of about 30 Å to about 300 Å, and the thickness of the electron transport layer may be in a range of about 150 Å to about 500 Å. In case that the thickness of the buffer layer, the hole blocking layer, the electron control layer, the electron transport layer, and/or the electron transport layer are within these ranges, satisfactory electron transporting characteristics may be obtained without a substantial increase in driving voltage.

The electron transport region 170 (for example, an electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion complex, with the metal ion of the alkali metal complex or with the metal ion of the alkaline earth-metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) or Compound ET-D2:

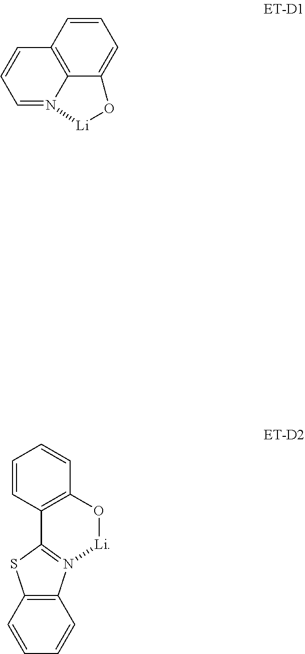

The electron transport region 170 may include an electron injection layer that facilitates the injection of electrons from the second electrode 190. The electron injection layer may contact (e.g., directly contact) the second electrode 190.

The electron injection layer may have a structure consisting of a layer consisting of a material, a structure consisting of a layer including different materials, or) a structure including multiple layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, and the like), or tellurides of the alkali metal, the alkaline earth metal, and the rare earth metal, or any combination thereof.

The alkali metal-containing compound may include: an alkali metal oxide, such as Li₂O, Cs₂O, K₂O, and the like; alkali metal halides, such as LiF, NaF, CsF, KF, LiI, NaI, CsI, KI, and the like; or any combination thereof. The alkaline earth metal-containing compound may include an alkaline earth metal compound, such as BaO, SrO, CaO, BaxSr₁₋ₓO (wherein x is a real number satisfying 0<x<1), BaxCa₁₋ₓO (wherein x is a real number satisfying 0<x<1), and the like. The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include one of alkali metal ions, alkaline earth metal ions, and rare earth metal ions, and a ligand bonded to the metal ion (for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.)

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (for example, a compound represented by Formula 601).

In an embodiment, the electron injection layer may consist of an alkali metal-containing compound (for example, alkali metal halide), or the electron injection layer may consist of an alkali metal-containing compound (for example, alkali metal halide), and an alkali metal, an alkaline earth metal, a rare earth metal, or any combination thereof. For example, the electron injection layer may be a KI:Yb co-deposited layer, an Rbl:Yb co-deposited layer, a LiF:Yb co-deposited layer, or the like.

In case that the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. In case that the thickness of the electron injection layer is within the ranges above, satisfactory electron injection characteristics may be obtained without a substantial increase in driving voltage.

### [Second Electrode 190]

The second electrode 190 may be disposed on an upper surface of the electron transport region 170 as described above. The second electrode 190 may be a cathode, which is an electron injection electrode. A material for forming the second electrode 190, may be a material having a low work function, for example, a metal, an alloy, an electrically conductive compound, or any combination thereof.

The second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 190 may be a transmissive electrode, a semi-transmissive electrode, or a reflective electrode.

The second electrode 190 may have a single-layered structure or a multi-layered structure.

The electronic apparatus 200A (for example, a light-emitting apparatus) may further include, in addition to the light-emitting device 10A, a color filter, a color conversion layer, or a color filter and a color conversion layer. The color filter and/or the color conversion layer may be disposed on a path of light emitted from the light-emitting device 10A. For example, light emitted from the light-emitting device 10A may be green light, blue light, or white light. For details of the light-emitting device 10A, related descriptions provided above may be referred to. In an embodiment, the color conversion layer may include a quantum dot. The quantum dot may be, for example, the quantum dot as described herein.

The electronic apparatus 200A may further include a thin-film transistor, in addition to the light-emitting device 10A as described above. The thin-film transistor may include a source electrode, a drain electrode, and an activation layer, and one of the source electrode and the drain electrode may be electrically connected to one of the first electrode 110 and the second electrode 190 of the light-emitting device 10A.

The thin-film transistor may further include a gate electrode, a gate insulating film, and the like.

The activation layer may include crystalline silicon, amorphous silicon, an organic semiconductor, an oxide semiconductor, or the like.

The electronic apparatus 200A may further include a sealing portion that seals the light-emitting device 10A. The sealing portion may be disposed between the color filter and/or color conversion layer and the light-emitting device 10A. The sealing portion transmit light from the light-emitting device 10A to the outside, and simultaneously prevents air and moisture from penetrating into the light-emitting device 10. The sealing portion may be a sealing substrate including a transparent glass substrate or a plastic substrate. The sealing portion may be a thin-film encapsulation layer including at least one of an organic layer and an inorganic layer. In case that the sealing portion is a thin film encapsulation layer, the electronic apparatus 200A may be flexible.

Various functional layers may be additionally arranged on the sealing portion, in addition to the color filter and/or the color conversion layer, according to the use of the electronic apparatus 200A. Examples of the functional layers may include a touch screen layer, a polarizing layer, and the like. The touch screen layer may be a pressure-sensitive touch screen layer, a capacitive touch screen layer, an infrared touch screen layer, or the like. The authentication apparatus may be, for example, a biometric authentication apparatus that authenticates an individual by using biometric information of a living body (for example, fingertips, pupils, and the like).

The authentication apparatus may further include, in addition to the organic light-emitting device 10A, a biometric information collector.

The electronic apparatus 200A may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

### Definitions of Terms

The term “C₃-C₆₀ carbocyclic group” as used herein may be a cyclic group consisting of carbon as the only ring-forming atoms and having three to sixty carbon atoms, and the term “C₁-C₆₀ heterocyclic group” as used herein may be a cyclic group that has one to sixty carbon atoms and further has, in addition to carbon, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of the C₁-C₆₀ heterocyclic group may be from 3 to 61.

The “cyclic group” as used herein may be a C₅-C₆₀ carbocyclic group or a C₁-C₆₀ heterocyclic group.

The term “π electron-rich C₃-C₆₀ cyclic group” as used herein may be a cyclic group that has three to sixty carbon atoms and may not include *—N=*′ as a ring-forming moiety, and the term “π electron-deficient nitrogen-containing C₁-C₆₀ cyclic group” as used herein may be a heterocyclic group that has one to sixty carbon atoms and may include *—N═*′ as a ring-forming moiety.

In an embodiment,
a C₅-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which at least two T2 groups are condensed with each other, or) a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),
a π electron-rich C₃-C₆₀ cyclic group may be a T1 group, a group in which at least two T1 groups are condensed with each other, a T3 group, a group in which at least two T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, or the like),
a π electron-deficient nitrogen-containing C₁-C₆₀ cyclic group may be a T4 group, a group in which at least two T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
wherein the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “IT electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, and the like) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group or a monovalent C₁-C₆₀ heterocyclic group may include a C₅-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein may be a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A¹⁰¹) (wherein A¹⁰¹ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group of 1 to 10 carbon atoms, further including, in addition to carbon atoms, at least one heteroatom, as ring-forming atoms, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has three to ten carbon atoms and at least one carbon-carbon double bond in the ring thereof and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group of 1 to 10 carbon atoms, further including, in addition to carbon atoms, at least one heteroatom, as ring-forming atoms, and having at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. In case that the C₆-C₆₀ aryl group and the C₆-C₆₀ arylene group each include two or more rings, the respective rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom, as ring-forming atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. In case that the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and no aromaticity in its entire molecular structure. Examples of a monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein may be a divalent group having a same structure as the monovalent non-aromatic condensed polycyclic group described above.

The term “monovalent non-aromatic condensed heteropolycyclic group” as used herein may be a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having a same structure as the monovalent non-aromatic condensed heteropolycyclic group described above.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄) (A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆) (A₁₀₇) (wherein A₁₀₆ may be a C₁-C₅₉ alkylene group, and A₁₀₇ may be a C₁-C₅₉ heteroaryl group).

The group “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁) (Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein may be any atom other than a carbon atom or a hydrogen atom. Examples of a heteroatom may include O, S, N, P, Si, B, Ge, Se, and any combination thereof.

In the specification, the term “third-row transition metal” may be hafnium (Hf), tantalum (Ta), tungsten (W), rhenium (Re), osmium (Os), iridium (Ir), platinum (Pt), gold (Au), or the like.

In the specification, “Ph” may be a phenyl group, “Me” may be a methyl group, “Et” may be an ethyl group, “ter-Bu” or “But” may each be a tert-butyl group, and “OMe” may be a methoxy group.

The term “biphenyl group” as used herein may be “a phenyl group substituted with a phenyl group.” For example, the “biphenyl group” may be a substituted phenyl group having a C₆-C₆₀ aryl group as a substituent.

The term “terphenyl group” as used herein may be “a phenyl group substituted with a biphenyl group.” For example, the “terphenyl group” may be a substituted phenyl group having, as a substituent, a C₆-C₆₀ aryl group substituted with a C₆-C₆₀ aryl group.

The symbols * and *′ as used herein, unless defined otherwise, may each be a binding site to a neighboring atom in a corresponding formula or moiety.

Hereinafter, embodiments of the quantum dot preparation method and the quantum dot prepared according to the same will be described in detail with reference to the Examples and the Comparative Examples.

### EXAMPLES

### Example 1: Manufacture of AgInₓGa₁₋ₓS₂/AgGaS_{X} (1.6 nm/1.2 nm) Quantum Dot

### Manufacture of Ag₂S Particle (Silver (Ag)-Containing Precursor) (Third Composition)

0.1 mmol of silver iodide (AgI), which is a silver (Ag)-containing first precursor and 5 ml of oleylamine were mixed, and heated in a vacuum condition while maintaining 50° C. until a clear solution was obtained. The resultant solution was stirred under N₂ atmosphere while maintaining 50° C. 1-dodecanethiol (DDT) and S-oleylamine, which are a sulfur (S)-containing second precursor, were mixed with the clear solution to form Ag₂S particles (Ag-containing precursor).

### Manufacture of Indium (In)-Containing Precursor

10 mmol of indium (III) oleate (In(OAc)₃) and 20 ml of 1-octadecene were mixed and stirred while maintaining 150° C. until a clear solution was obtained to manufacture an In-containing precursor.

### Manufacture of Gallium (Ga)-Containing Precursor

10 mmol of gallium (III) oleate and 20 ml of 1-octadecene were mixed and stirred while maintaining 150° C. until a clear solution was obtained to manufacture a gallium (Ga)-containing precursor.

### Manufacture of Core (First Composition)

0.05 mmol of the manufactured In-containing precursor and 0.1 mmol of the manufactured Ga-containing precursor were mixed with 0.1 mmol of the manufactured Ag₂S particles (Ag-containing precursor), and the mixture was stirred at 210° C. for 30 minutes to manufacture a AgInₓGa₁₋ₓS₂ core.

### Manufacture of First Shell (Second Composition)

0.2 mmol of the manufactured Ag₂S particles (Ag-containing precursor), 0.2 mmol of the manufactured Ga-containing precursor, and 0.4 mmol of S-oleylamine, which is an S-containing precursor were mixed with the manufactured core, and the mixture was stirred at 240° C. for 60 minutes to manufacture a AgInₓGa₁₋ₓS₂/AgGaSₓ quantum dot of Example 1.

### Example 2: Manufacture of AgInₓGa₁₋ₓS₂/AgGaSₓ (1.6 nm/2.5 nm) Quantum Dot

A quantum dot shown in Table 2 below was manufactured in the same manner as in Example 1, except that, in manufacturing the first shell of Example 2, 1 mmol of the Ag₂S particles, 1 mmol of the manufactured Ga-containing precursor, and 2 mmol of S-oleylamine, which is a S-containing precursor, were mixed and stirred for 180 minutes.

### Example 3: Manufacture of AgInₓGa₁₋ₓS₂/AgGaSₓ (1.6 nm/3.4 nm) Quantum Dot

A quantum dot shown in Table 2 below was manufactured in the same manner as in Example 1, except that, in manufacturing the first shell of Example 3, 3 mmol of the Ag₂S particle, 3 mmol of the manufactured Ga-containing precursor, and 6 mmol of S-oleylamine, which is an S-containing precursor, were mixed and stirred for 300 minutes.

### Example 4: Manufacture of AgInₓGa₁₋ₓS₂/AgGaSₓ (1.6 nm/1.2 nm) Quantum Dot

Manufacture of Ag₂S Particles (A¹-B¹-Containing Precursor) (Third Composition)

0.1 mmol of silver iodide (AgI), which is an Ag-containing first precursor and 5 ml of oleylamine were mixed, and heated in a vacuum condition while maintaining 50° C. until a clear solution was obtained. The resultant solution was stirred under N₂ atmosphere while maintaining 50° C. 1-dodecanethiol (DDT) and S-oleylamine, which are a S-containing second precursor, were mixed into the clear solution to form Ag₂S particles (Ag-containing precursor).

Manufacture of Indium (in)-Containing Precursor

10 mmol of indium (III) oleate (In(OAc)3) and 20 ml of 1-octadecene were mixed and stirred while maintaining 150° C. until a clear solution was obtained to manufacture an In-containing precursor.

### Manufacture of Gallium (Ga)-Containing Precursor

10 mmol of gallium (III) oleate and 20 ml of 1-octadecene were mixed and stirred while maintaining 150° C. until a clear solution was obtained to manufacture a Ga-containing precursor.

Manufacture of Intermediate (A¹-A²-B¹-Containing Precursor) (Fourth Composition)

0.1 mmol of H₂S was mixed with 0.1 mmol of the manufactured Ag₂S particle (Ag-containing precursor), and the mixture was stirred to form AgSH. The manufactured AgSH was mixed with 0.1 mmol of the manufactured Ga-containing precursor, and the mixture was stirred at 130° C. for 30 minutes to form Intermediate, AgSGa(OAc)₂.

### Manufacture of Core (First Composition)

0.05 mmol of the manufactured In-containing precursor and 0.1 mmol of S-oleyamine, which is an S-containing precursor, were mixed with 0.1 mmol of the manufactured Intermediate, AgSGa(OAc)₂, and the mixture was stirred at 210° C. for 30 minutes to manufacture a AgInₓGa₁₋ₓS₂ core.

### Manufacture of First Shell (Second Composition)

0.2 mmol of the manufactured Intermediate, AgSGa(OAc)₂, and 0.2 mmol of S-oleylamine, which is an S-containing precursor, were mixed with the manufactured core, and the mixture was stirred at 240° C. for 60 minutes to manufacture a AgInₓGa₁₋ₓS₂/AgGaSₓ quantum dot of Example 4.

### Comparative Example 1

A quantum dot was prepared in the same manner as in Example 1, except that the manufacturing of first shell in Example 1 was omitted.

### Comparative Example 2

A quantum dot was prepared in the same manner as in Example 1, except that, in manufacturing the first shell of Comparative Example 2, Ag₂S particles were not mixed, and the mixture was stirred for 120 minutes.

### Comparative Example 3

A quantum dot was prepared in the same manner as in Example 1, except that, in manufacturing the first shell of Comparative Example 3, Ag₂S particle was not mixed, and the mixture was stirred for 180 minutes.

### Comparative Example 4

A quantum dot was prepared in the same manner as in Example 1, except that, in manufacturing the first shell of Comparative Example 4, Ag₂S particle was not mixed, and the mixture was stirred for 240 minutes.

### Comparative Example 5

A quantum dot was prepared in the same manner as in Example 1, except that, in manufacturing the first shell of Comparative Example 5, Ag₂S particle was not mixed, and the mixture was stirred for 300 minutes.

### Evaluation Result 1 (Photoluminescence Spectrum)

The photoluminescence spectrum of Example 3 and Comparative Examples 1 and 2 measured by using UV-1900i is shown in FIG. 4. The atomic ratio of Ag to In in quantum dot were measured by ICP-OED using Perkin-Elme OPTIMA-4300DV, and the maximum emission wavelength (λₘₐₓ, nm) in the photoluminescence spectrum of FIG. 4 are shown in Table 1 below.

The luminescence efficiencies of the quantum dots according to Example 3 and Comparative Examples 1 and 2 were measured by using Shimadzu UV-1800 and Horiba FluoroMax-4. The results are shown in Table 1 below.

TABLE 1

| | Atomic ratio | λₘₐₓ | Luminescence |
|---|---|---|---|
| | of Ag to In | (nm) | efficiency (%) |
| Example 3 | 2.2 | 517 | 95 |
| Comparative | 0.6 | — | 10 |
| Example 1 | | | |
| Comparative | 0.6 | 522 | 40 |
| Example 2 | | | |

According to FIG. 4 and Table 1, unlike the quantum dot of Example 3, it may be seen that the quantum dot of Comparative Example 2 has a side peak in addition to a peak at the maximum emission wavelength. Accordingly, as the quantum dot of Example 3 has no side peak as opposed to the quantum dots of Comparative Examples 1 and 2, it may be seen the luminescence efficiency of the quantum dot of Example 3 was improved.

### Evaluation Result 2

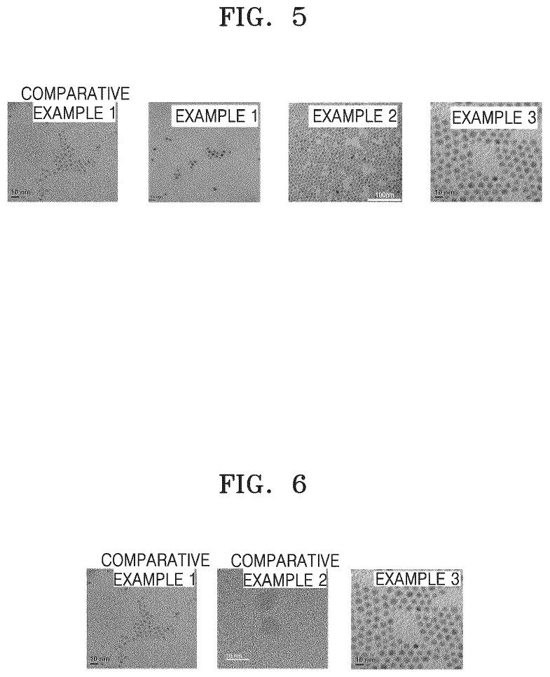

The atomic ratios of Ag to In in the quantum dots of Examples 1 to 4 and Comparative Examples 1 to 5 were measured by ICP-OES using OPTIMA-4300DV of Perkin-Elme, and the radius of the core and thicknesses of the first shell and/or the second shell were measured by high resolution transmission electron microscope (HR-TEM) analysis. Images of Comparative Example 1, Example 1, Example 2, and Example 3 are shown in FIG. 5, and images of Comparative Example 1, Comparative Example 2, and Example 3 are shown in FIG. 6.

By using Shimadzu UV-1800, 450 nm excitation was conducted, and the absorbance was set to 0.1 for measurement of photoluminescence spectrum of the quantum dots of Examples 1 to 4 and Comparative Example 1 to 5 to measure a peak at the maximum emission wavelength and an FWHM in the photoluminescence spectrum. The luminescence efficiencies of the quantum dots of Examples 1 to 4 and Comparative Examples 1 to 5 were measured by using HoribaFluoroMax-4, and the results thereof are shown in Table 2 below.

TABLE 2

| | | Thickness | | Peak | Absorbance | | |
|---|---|---|---|---|---|---|---|
| | Atomic | Radius | Thickness | wavelength of | @450 nm | | |
| | ratio of | of core | of first | PL emission | absorption | Luminescence | FWHM |
| | Ag to In | (nm) | shell (nm) | spectrum (nm) | rate | efficiency (%) | (nm) |
| Comparative | 0.6 | 1.6 | 0 | — | 0.1 | 10 | — |
| Example 1 | | | | | | | |
| Comparative | 0.6 | 1.6 | 1.0 | 522 | 0.1 | 40 | 39 |
| Example 2 | | | | | | | |
| Comparative | 0.6 | 1.6 | 1.2 | 522 | 0.1 | 45 | 38 |
| Example 3 | | | | | | | |
| Comparative | 0.6 | 1.6 | 2.5 | 522 | 0.1 | 52 | 36 |
| Example 4 | | | | | | | |
| Comparative | 0.6 | 1.6 | 3.4 | 521 | 0.1 | 55 | 36 |
| Example 5 | | | | | | | |
| Example 1 | 1.3 | 1.6 | 1.2 | 519 | 0.1 | 60 | 35 |
| Example 2 | 1.6 | 1.6 | 2.5 | 516 | 0.1 | 90 | 33 |
| Example 3 | 2.2 | 1.6 | 3.4 | 517 | 0.1 | 95 | 32 |
| Example 4 | 1.4 | 1.6 | 1.2 | 520 | 0.1 | 94 | 31 |

From Table 2, it may be seen that the quantum dots of Examples 1 to 4 have excellent luminescence efficiency and low FWHM, compared to the quantum dots of Comparative Examples 1 to 5.

According to embodiments, a core and a first shell of a quantum dot may each include Ag in an amount satisfying an atomic ratio, and thus the quantum dot may have excellent luminescence efficiency and high absorbance characteristics while maintaining stability. Accordingly, a high-quality optical member and electronic apparatus may be provided by using the quantum dot.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A quantum dot comprising:
a core comprising indium (In) and A¹; and
a first shell covering the core, not including In, and including A¹, wherein
A¹ is a Group I element,
an atomic ratio of A¹ to In in the quantum dot is in a range of about 0.9 to about 2.4, and
the quantum dot emits visible light other than blue light.

2. The quantum dot of claim 1, wherein
the core further comprises at least one of A² and B¹,
A² is a Group III element other than In, and
B¹ is a Group VI element.

3. The quantum dot of claim 1, wherein
the first shell further includes at least one of A³ and B²,
A³ is a Group III element other than In, and
B² is a Group VI element.

4. The quantum dot of claim 1, wherein the core and the first shell each independently comprise a Group I-III-VI semiconductor compound.

5. The quantum dot of claim 1, wherein the core comprises a first semiconductor compound represented by Formula 1: 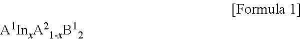
wherein in Formula 1,
A¹ is the Group I element,
A² is a Group III element other than indium,
B¹ is a Group VI element, and
x is a real number in a range of about 0.1 to about 0.6.

6. The quantum dot of claim 1, wherein the first shell comprises a second semiconductor compound represented by Formula 2: 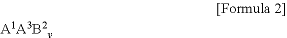
wherein in Formula 2,
A¹ is the Group I element,
A³ is a Group III element other than In,
B² is a Group VI element, and
y is a real number in a range of about 0.5 to about 2.

7. The quantum dot of claim 1, wherein a maximum emission wavelength of the quantum dot is in a range of about 500 nm to about 650 nm.

8. The quantum dot of claim 1, wherein a full width at half maximum (FWHM) of an emission wavelength spectrum of the quantum dot is in a range of about 30 nm to about 35 nm.

9. The quantum dot of claim 1, wherein a photoluminescence quantum yield (PLQY) of the quantum dot is in a range of about 50% to about 98%.

10. An optical member comprising the quantum dot of claim 1.

11. An electronic apparatus comprising the quantum dot of claim 1.

12. The electronic apparatus of claim 11, further comprising:
a light source; and
a color conversion member disposed on a pathway of light emitted from the light source,
wherein the color conversion member comprises the quantum dot.

13. The electronic apparatus of claim 11, further comprising:
a light-emitting device comprising:
a first electrode;
a second electrode facing the first electrode; and
an emission layer between the first electrode and the second electrode,
wherein the light-emitting device comprises the quantum dot.

14. A method of preparing a quantum dot, the method comprising:
manufacturing a core comprising indium (In) and A¹ by using a first composition comprising an In-containing precursor and an A¹-containing precursor; and
manufacturing a first shell covering the core and comprising A¹ by using a second composition comprising the core and the A¹-containing precursor,
wherein A¹ is a Group I element.

15. The method of claim 14, wherein
an atomic ratio of A¹ to In in the quantum dot is in a range of about 0.9 to about 2.4, and
the quantum dot emits visible light other than blue light.

16. The method of claim 14, further comprising:
manufacturing the A¹-containing precursor in the first composition by using a third composition comprising an A¹-containing first precursor and a B¹-containing second precursor.

17. The method of claim 14, wherein
the A¹-containing precursor in the first composition is an A¹-B¹-containing precursor which further comprises B¹, and
B¹ is a Group VI element.

18. The method of claim 14, wherein
the A¹-containing precursor in the first composition is an A¹-A²-B¹-containing precursor which further comprises A² and B¹,
A² is a Group III element other than In,
B¹ is a Group VI element, and
the method further comprises manufacturing the A¹-A²-B¹-containing precursor by using a fourth composition comprising an A¹-B¹-containing precursor and an A²-containing precursor, before the manufacturing of the core.

19. The method of claim 14, wherein
the first composition further comprises an A²-containing precursor,
the core further comprises A², and
A² is a Group III element other than In.

20. The method of claim 14, wherein
the second composition further comprises at least one of an A³-containing precursor and a B²-containing precursor,
the first shell further comprises at least one of A³ and B²,
A³ is a Group III element other than In, and
B² is a Group VI element.
